(19) United States
(12) Patent Application Publication
(10) Pub. No.: US 2024/0021242 A1
(43) Pub. Date: Jan. 18, 2024

(54) MEMORY-BASED NEUROMORPHIC DEVICE AND OPERATING METHOD THEREOF

(71) Applicant: SK hynix Inc., Gyeonggi-do (KR)

(72) Inventors: Sang Su Park, Gyeonggi-do (KR); Se Ho Lee, Gyeonggi-do (KR); Young Jae Kwon, Gyeonggi-do (KR); Geon Hui Lee, Gyeonggi-do (KR)

(21) Appl. No.: 17/987,100

(22) Filed: Nov. 15, 2022

(30) Foreign Application Priority Data
Jul. 12, 2022 (KR) 10-2022-0085782

(51) Int. Cl. G11C 11/54; G11C 13/00

(52) U.S. Cl. CPC G11C 11/54; G11C 13/0026; G11C 13/0028; G11C 13/004; G11C 13/0069; G11C 2013/0054

(57) ABSTRACT

A Computation-in-Memory (CiM) device includes a plurality of first synaptic cells disposed between row lines and column lines and configured to output read currents to the column lines, the read currents corresponding to pulse signals applied through the row lines; a plurality of second synaptic cells disposed between the row lines and two or more reference column lines and configured to output two or more reference read currents to the reference column lines, the reference read currents corresponding to the pulse signals applied through the row lines; and a column control circuit configured to output digital data by compensating for the read currents output through the column lines, based on the reference read currents output through the reference column lines.

### CROSS-REFERENCE TO RELATED APPLICATION

The present application claims the benefit of Korean Patent Application No. 10-2022-0085782, filed on Jul. 12, 2022, which is incorporated herein by reference in its entirety.

### BACKGROUND

### 1. Field

Various embodiments of the present invention relate to a semiconductor design technology, and more particularly, to a memory-based neuromorphic device.

### 2. Description of the Related Art

Artificial neural networks (ANNs) similar to biological neural networks are in the spotlight. The artificial neural networks are used in various fields such as machine learning, selection, reasoning, prediction, recognition, analysis, translation, and diagnosis. The artificial neural networks may include artificial neurons that are similar to neurons which are nerve cells, and form multiple layers. The synaptic weight may represent the strength of a connection between artificial neurons and may be learned and changed through machine learning.

With the recent increase in the number of layers of artificial neural networks and the number of artificial neurons, the number of synaptic weights and biases representing the strength of connections between artificial neurons is also increasing. When an artificial neural network is implemented in a hardware manner in a semiconductor chip, high-intensity technology and low-power technology are required to store increasing synaptic weights and biases and implement multiple artificial neurons.

### SUMMARY

Embodiments of the present invention are directed to a neuromorphic device capable of compensating for an IR drop (or a voltage drop) of a column line by using reference synaptic cells, and an operation method thereof.

According to an embodiment of the present invention, a Computation-in-Memory (CiM) device includes a plurality of first synaptic cells disposed between a plurality of row lines and a plurality of column lines and configured to output a plurality of read currents to the column lines, the read currents corresponding to pulse signals applied through the row lines; a plurality of second synaptic cells disposed between the row lines and two or more reference column lines and configured to output two or more reference read currents to the reference column lines, the reference read currents corresponding to the pulse signals applied through the row lines; and a column control circuit configured to output digital data by compensating for the read currents output through the column lines, based on the reference read currents output through the reference column lines.

According to an embodiment of the present invention, a neuromorphic device includes a plurality of pre-synaptic neurons; a plurality of first synaptic cells coupled to the pre-synaptic neurons through a plurality of row lines and configured to output a plurality of read currents through a plurality of column lines; a plurality of second synaptic cells coupled to the pre-synaptic neurons through the row lines and configured to output two or more reference read currents through respective reference column lines; and a plurality of post-synaptic neurons coupled to the first synaptic cells through the column lines and coupled to the second synaptic cells through the reference column lines and configured to output digital signals by compensating for the read currents output through the column lines based on the reference read currents output through the reference column lines.

According to an embodiment of the present invention, an operating method of a Computation-in-Memory (CiM) device includes applying, through a plurality of row lines, pulse signals corresponding to pixel data to a plurality of first synaptic cells and a plurality of second synaptic cells, the first synaptic cells being disposed between the row lines and a plurality of column lines and the second synaptic cells being disposed between the row lines and two or more reference column lines; outputting a plurality of read currents corresponding to the pulse signals through the column lines; outputting two or more reference read currents corresponding to the pulse signals through the respective reference column lines; and outputting digital data by compensating for the read currents output through the column lines based on the reference read currents output through the reference column lines.

According to an embodiment of the present invention, a device includes first synaptic cells arranged in rows and first columns and configured to generate data currents through the respective first columns in response to input signals applied to the respective rows; second synaptic cells arranged in the rows and second columns and configured to generate reference currents through the respective second columns in response to the input signals; and a control circuit configured to generate a replica current based on the reference currents and configured to generate digital data by subtracting the replica current from each of one or more of the data currents, wherein the second columns are of an even number, wherein the second synaptic cells arranged in an odd one of the second columns are in a high-resistance state (HRS), and wherein the second synaptic cells arranged in an even one of the second columns are in a low-resistance state (LRS).

According to embodiments of the present invention, the ferroelectric memory device may ensure reliability of an operation thereof by performing a normal operation in a state in which target characteristics may be ensured by performing a recovery operation during an initial operation.

### BRIEF DESCRIPTION OF THE DRAWINGS

FIGS. 1A and 1B are diagrams for describing a biological neuron and a mathematical model that simulates an operation of the biological neuron in accordance with an embodiment of the present invention.

FIGS. 2A and 2B are diagrams for describing an operating method of a neuromorphic device in accordance with an embodiment of the present invention.

FIGS. 3A and 3B are diagrams for comparing vector-matrix multiplication and a computation performed in a crossbar array device in accordance with an embodiment of the present invention.

FIG. 4 is a block diagram illustrating a Computation-in-Memory (CiM) device in accordance with an embodiment of the present invention.

FIGS. 5A and 5B are a block diagram and a timing diagram illustrating a row control circuit of FIG. 4 in accordance with an embodiment of the present invention.

FIGS. 6A to 6C are diagrams for describing first and second synaptic arrays in accordance with an embodiment of the present invention.

FIG. 7 is a circuit diagram illustrating a column control circuit of FIG. 4 in accordance with an embodiment of the present invention.

FIG. 8 is a diagram for describing first and second synaptic arrays in accordance with another embodiment of the present invention.

FIG. 9 is a circuit diagram illustrating the column control circuit of FIG. 4 in accordance with another embodiment of the present invention.

FIG. 10 is a flowchart illustrating an operating method of a CiM device in accordance with an embodiment of the present invention.

FIG. 11 is a diagram for describing a pattern recognition system including a neuromorphic device in accordance with an embodiment of the present invention.

### DETAILED DESCRIPTION

Specific structural and functional descriptions provided herein are directed to embodiments of the present disclosure. The present invention, however, is not limited to the embodiments described herein.

While embodiments are described in detail, the present invention is not limited to any specific detail. The present disclosure may be embodied in many different forms and should not be construed as being limited to any specific description. Rather, the present invention should be construed to cover not only the disclosed embodiments, but also various alternatives, modifications, equivalents, and other embodiments that fall within the spirit and scope of the present disclosure.

It will be understood that, although the terms “first”, “second”, etc. may be used herein to identify various elements, these elements should not be limited by these terms. These terms are only used to distinguish one element from another element that otherwise have the same or similar names. A first element in one instance could be termed a second element in another instance without departing from the teachings of the present disclosure.

It will be understood that when an element is referred to as being “coupled” or “connected” to another element, it can be directly coupled or connected to the other element or one or more intervening elements may be present therebetween. In contrast, it should be understood that when an element is referred to as being “directly coupled” or “directly connected” to another element, there are no intervening elements present. Other expressions that describe the relationship between elements, such as “between”, “directly between”, “adjacent to” or directly adjacent to” should be construed in the same way.

The terminology used herein is for the purpose of describing particular embodiments only and is not intended to be limiting. In the present disclosure, the singular forms are intended to include the plural forms as well, unless the context clearly indicates otherwise. It will be further understood that open ended terms, such as “comprise”, “include”, “have”, etc., when used in this specification, specify the presence of stated features, integers, steps, operations, elements, components, and/or combinations of them but do not preclude the presence or addition of one or more other features, integers, steps, operations, elements, components, and/or combinations thereof.

Unless otherwise defined, all terms including technical and scientific terms used herein have the same meaning as commonly understood by one of ordinary skill in the art to which the present disclosure belongs. It will be further understood that terms used herein should be interpreted as having a meaning that is consistent with their meaning in the context of this specification and the relevant art and not be interpreted in an idealized or overly formal sense unless expressly so defined herein.

Detailed description of functions and structures well known to those skilled in the art may be omitted to avoid obscuring the subject matter of the present disclosure. This aims to omit unnecessary description to make the subject matter of the present disclosure clear.

Various embodiments of the present disclosure are described more fully below with reference to the accompanying drawings, in which preferred embodiments of the present disclosure are shown, so that those skilled in the art can easily carry out and practice the present disclosure.

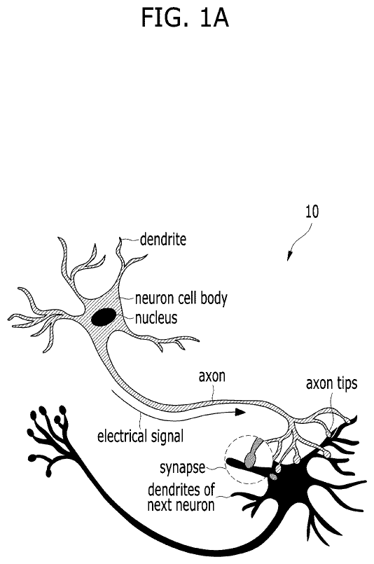

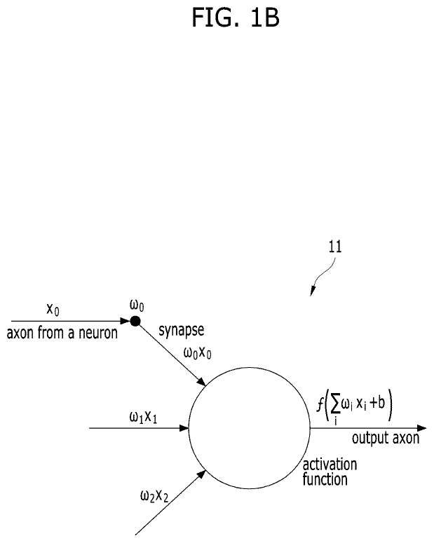

FIGS. 1A and 1B are diagrams for describing a biological neuron 10 and a mathematical model 11 that simulates an operation of the biological neuron in accordance with an embodiment of the present invention.

Referring to FIG. 1A, the biological neuron 10 refers to cells present in the human nervous system. The biological neuron 10 may be one of the basic biological computational objects. The human brain contains approximately 100 billion biological neurons and 100 trillion interconnects therebetween. The biological neuron 10 may be a single cell. The biological neuron 10 includes a neuron cell body comprising a nucleus and various organelles. Various cellular organs include mitochondria, multiple dendrites that radiate from the cell body, and axons that terminate at many branch extensions.

In general, the axons perform the function of transmitting signals from neurons to other neurons, and the dendrites perform the function of receiving signals from other neurons. For example, when different neurons are connected, the signal transmitted through the axon of the neuron may be received by the dendritic protrusion of the other neuron. At this time, signals between neurons are transmitted through specialized connections called synapses, and several neurons are connected to each other to form a neural network. Neurons that secrete neurotransmitters with synapses as references may be referred to as pre-synaptic neurons, and neurons that receive information transmitted through neurotransmitters may be referred to as post-synaptic neurons.

Moreover, the human brain may learn and remember vast amounts of information by transmitting and processing various signals through neural networks formed by connecting large numbers of neurons to each other. The vast number of connections between neurons in the human brain are directly correlated with the massively parallel nature of biological computing, and various attempts have been made to efficiently process vast amounts of information by simulating artificial neural networks. For example, a neuromorphic device is being studied as a computing system designed to implement artificial neural networks at the neuron level.

Referring to FIG. 1B, an operation of the biological neuron 10 may be simulated as the mathematical model 11. The mathematical model 11 corresponding to the biological neuron 10 is an example of a neuromorphic operation, which may include a multiplication computation that multiplies synaptic weights for information from multiple neurons, an addition computation Σ that adds values ω0x0, ω1x1, ω2x2 obtained by multiplying the synaptic weight, and a computation that applies a characteristic function b and an activation function f to a result of the addition computation. A neuromorphic computation result may be provided by the neuromorphic operation. Here, the numeral reference “x0, x1, x2, . . . ” may correspond to axon values, the numeral reference “ω0, ω1, ω2, . . . ” may correspond to synaptic weights.

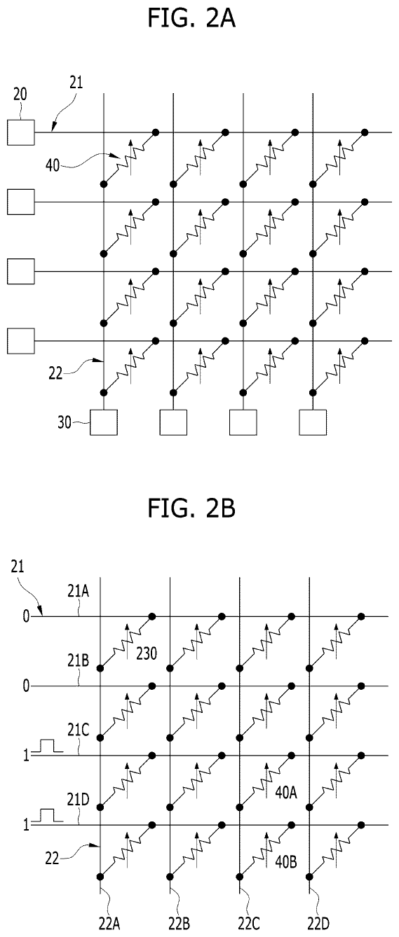

FIGS. 2A and 2B are diagrams for describing an operating method of a neuromorphic device in accordance with an embodiment of the present invention.

Referring to FIG. 2A, the neuromorphic device may include a crossbar device circuit. The crossbar array device may include a plurality of crossbar array circuits. Each of the crossbar array circuits may be implemented with a resistive crossbar memory array (RCA). In detail, the crossbar array circuit may include a plurality of pre-synaptic neurons 20, a plurality of post-synaptic neurons 30, and a plurality of synapse cells (i.e., synapses) 40.

Though FIG. 2A shows the crossbar array circuit of the neuromorphic device including 4 pre-synaptic neurons 20, 4 post-synaptic neurons 30, and 16 synapses 40, the numbers may vary and are not limited thereto. When the number of pre-synaptic neurons 20 is N (here, N is a natural number equal to or greater than 2) and the number of post-synaptic neurons 30 is M (here, M is a natural number equal to or greater than 2 and may or may not be the same as N), N*M synapses 40 may be arranged in a matrix shape.

In detail, a plurality of lines 21 may be coupled to the pre-synaptic neurons 20 and extend in a first direction (e.g., a latitudinal or row direction), and a plurality of lines 22 may be coupled to the neuron circuit 30 and extend in a second direction (e.g., a longitudinal or column direction) crossing the first direction. Hereinafter, for convenience of description, the line 21 extending in the first direction may be referred to as a row line, and the line 22 extending in the second direction may be referred to as a column line. A plurality of synapses 40 may be arranged at respective intersections of the row lines 21 and the column lines 22, thereby connecting corresponding row lines 21 and corresponding column lines 22.

The pre-synaptic neuron 20 may generate a signal corresponding to particular data, and transmit the signal to the row line 21, whereas the post-synaptic neuron 30 may receive a synaptic signal from the synapse 40 through the column line 22 and process the synaptic signal. The pre-synaptic neuron 20 may correspond to an axon, and the post-synaptic neuron 30 may correspond to a neuron. However, whether it is a presynaptic neuron or a postsynaptic neuron may be determined by a relative relationship with another neuron. For example, when the pre-synaptic neuron 20 receives a synaptic signal in relation to another neuron, it may function as the post-synaptic neuron. Similarly, when the post-synaptic neuron 30 transmits a signal in relation to another neuron, it may function as the pre-synaptic neuron.

A connection between the pre-synaptic neurons 20 and the post-synaptic neuron 30 may be established through the synapses 40. Here, the synapses 40 may be an element whose electrical conductance or weight is changed according to an electrical pulse (e.g., a voltage or a current) applied to both ends thereof.

The synapses 40 may include, for example, a variable resistance element. A variable resistance device may be a device that may be switched between different resistance states according to a voltage or a current applied to both ends thereof and may have a single layer structure or a multi-layered structure including various materials that may have a plurality of resistance states, e.g., metal oxides such as transition metal oxides and perovskite-based materials, phase-change materials such as chalcogenide materials, ferroelectric materials, ferromagnetic materials, etc. An operation in which the variable resistance element and/or the synapses 40 is changed from a high resistance state to a low resistance state may be referred to as a set operation, whereas an operation in which the variable resistance element and/or the synapses 40 is changed from a low resistance state to a high resistance state may be referred to as a reset operation.

Referring to FIG. 2B, an operation of the neuromorphic device is shown. For convenience of description, the row lines 21 may include first to fourth row lines 21A to 21D, and the column lines 22 may include first to fourth column lines 22A to 22D. In an initial state, all of the synapses 40 may be in a state of relatively low conductivity, that is, a high resistance state. However, when some of the synapses 40 are in a low resistance state, an initialization operation for switching them into the high resistance state may be additionally performed. Each of the synapses 40 may have a predetermined threshold value for changing resistance and/or conductivity (e.g., where each of the synapses 40 may change resistance and/or conductivity when at least the predetermined threshold value of voltage or current is applied to the synapses 40). For example, when a voltage or a current having a magnitude smaller than the predetermined threshold value is applied to both ends of one of the synapses 40, the conductivity of the synapses 40 may not be changed (e.g., may be maintained). Alternatively or additionally, for example, when a voltage and/or a current having a magnitude greater than the predetermined threshold value is applied to the synapses 40, the conductivity of the synapses 40 may be changed.

In this state, to perform an operation for outputting particular data to a particular column line 22, an input signal corresponding to the particular data may be input to the row lines 21 through the pre-synaptic neurons 20. When the input signal is input to the row lines 21, the input signal may be applied to the row lines 21 as an electrical pulse. For example, when an input signal corresponding to binary data ‘0011’ is input through the row lines 21, the bits of the data may sequentially correspond to the row lines 21 such that no electrical pulse may be applied to the row lines 21 corresponding to ‘0’ bits of the data (e.g., first and second row lines 21A and 21B) and electrical pulses may be applied to the row lines 21 corresponding to ‘1’ bits of the data (e.g., third and fourth row lines 21C and 21D). When the input signal is input to the row lines 21, the particular column line 22 may be driven with a determined voltage or current.

For example, when a column line 22 to output the particular data is predetermined, the predetermined column line 22 may be driven, such that the synapses 40 located at the intersections of the determined column line 22 and the row lines 21 corresponding to ‘1’ receive a voltage having a magnitude equal to or greater than a predetermined minimum voltage (hereinafter referred to as a set voltage) with which the synapses 40 may perform a set operation, and remaining column lines 22 may be driven, such that the synapses 40 receives voltages having magnitudes smaller than that of the set voltage. For example, when the magnitude of the set voltage is Vset and a third column line 22C is determined as the column line 22 for outputting the data ‘0011’, the magnitudes of electrical pulses applied to the third and fourth row lines 21C and 21D may be equal to or greater than Vset and a voltage applied to the third column line 22C may be 0 V, such that first and second synapses 40A and 40B located at the intersections between the third column line 22C and the third and fourth row lines 21C and 21D receive voltages equal to or greater than Vset. When the first and second synapses 40A and 40B receive the voltages equal to or greater than Vset, the first and second synapses 40A and 40B may be in a low resistance state (e.g., a set operation where the first and second synapses 40A and 40B may be changed from a high resistance state to the low resistance state).

The conductivity of the first and second synapses 40A and 40B in the low resistance state may gradually increase as the number of electrical pulses increases. The magnitude and the width of electrical pulses applied thereto may be substantially constant. Voltages applied to remaining column lines (that is, first, second, and fourth column lines 22A, 22B, and 22D) may have a value (e.g., ½ Vset) between 0 V and Vset, such that remaining synapses 40 (e.g., the synapses 40 other than the first and second synapses 40A and 40B) receive a voltage smaller than Vset. When the remaining synapses 40 receive the voltage smaller than Vset, the resistance state of the remaining synapses 40 may not be changed (e.g., may be maintained).

In another example, when no particular column line 22 is predetermined to output particular data, a current flowing through each of the column lines 22 may be measured while applying electrical pulses corresponding to the particular data to the row lines 21, and the column line 22 (e.g., a third column line 22C) that first reaches a predetermined threshold current may be determined as the column line 22 to output the particular data.

By the methods described above with reference to FIGS. 2A to 2B, different data may be output to different column lines 22, respectively.

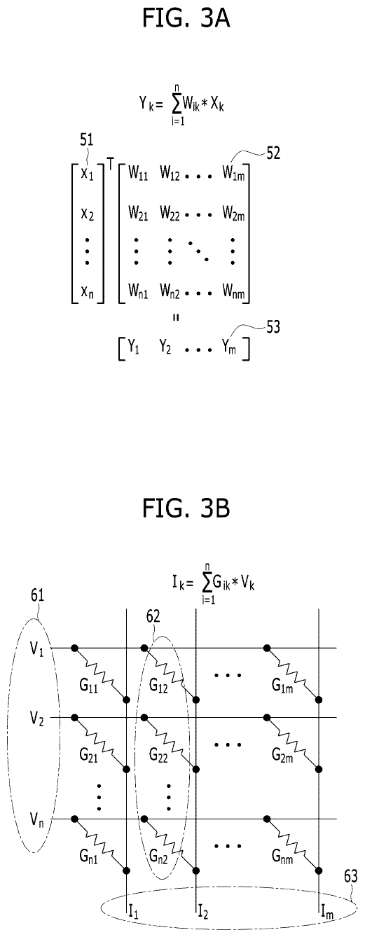

FIGS. 3A and 3B are diagrams for comparing vector-matrix multiplication and a computation performed in a crossbar array device in accordance with an embodiment of the present invention.

Referring to FIG. 3A, a convolution computation between an input feature map and a weight value may be performed by using a vector-matrix multiplication. For example, pixel data of the input feature map may be expressed as a matrix X 51, and weight values may be expressed as a matrix W 52. Pixel data of an output feature map may be expressed as a matrix Y 53, which is a result of a multiplication computation between the matrix X 51 and the matrix W 52.

Referring to FIG. 3B, a vector-matrix multiplication may be performed by using a non-volatile memory device of a crossbar array (e.g., the crossbar array device of FIGS. 2A to 2B). As compared to FIG. 3A, pixel data (e.g., the matrix X 51) of an input feature map may be received as an input value of the non-volatile memory device, and the input value may be a voltage 61. Also, weight values (e.g., the matrix W 52) may be stored in a synapse (that is, a memory cell) of the non-volatile memory device and the weight values stored in the memory cell may be conductance 62. Therefore, output values (e.g., the matrix Y 53) of the non-volatile memory device may be expressed as a current 63, which is a result of the multiplication between the voltage 61 and conductance 62.

Most of artificial intelligence (AI) operations are parallel Multiply-Accumulation (MAC) computations. Performing MAC computations in a conventional von-Neumann computing architecture is inefficient in terms of computational time and power. Therefore, various AI hardware operating architectures are emerging to address this concern. Among them, the architecture that attracts a lot of attention is an analog Computation-in-Memory (CiM) architecture that can operate and store simultaneously in the form of a nonvolatile memory (NVM)-based crossbar as described in FIG. 3B. The CiM device may directly calculate vector-matrix multiplication by reducing access to off-chip memory and reading current from the voltage and resistance values of each of the crossbar memory cells.

However, for inference and learning about complex image or voice patterns, the number of weight parameters required increases, and high density synaptic arrays are required for this. Ideal properties of synaptic cells, such as linearity, symmetry, and polymorphism, are also important, but since data are simultaneously read from all column lines during a read operation of the CiM device, the standby time and voltage may be increased and an IR drop (or a voltage drop) may be induced, due to parasitic components such as wire parasitic (Rw and Cw) in the crossbar array device, and on-resistance (Ron) of the conventional memory cell for single bit reading.

Hereinafter, in accordance with an embodiment of the present invention, a method of compensating for an IR drop in a neuromorphic device will be described. In the following embodiments, a CiM device among neuromorphic devices will be described as an example. However, the proposed invention is not limited thereto, and the configuration described in the following embodiments may be applied to a neuromorphic device.

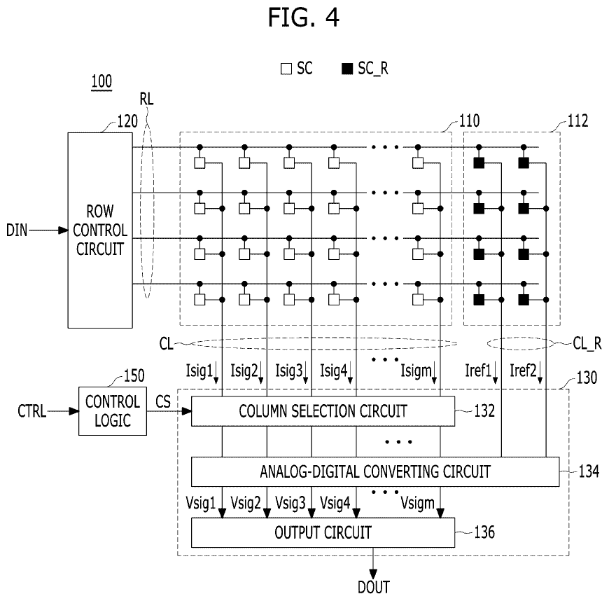

FIG. 4 is a block diagram illustrating a CiM device 100 in accordance with an embodiment of the present invention.

Referring to FIG. 4, the CiM device 100 may include at least one crossbar array circuit including a first synaptic array 110, a second synaptic array 112, a row control circuit 120, a column control circuit 130, and a control logic 150.

The CiM device 100 may be used to drive any neural network system and machine learning system, such as an artificial neural network (ANN) system, a convolutional neural network (CNN) system, a deep neural network (DNN) system, and a deep learning system. For example, various services and applications such as image classification service, biometric authentication service, Advanced Driver Assistance System (ADAS) service, voice assistant service, and automatic speech recognition (ASR) service may be executed by the CiM device 100.

The first synaptic array 110 may include a plurality of first synaptic cells SC disposed in an area where a plurality of row lines RL and a plurality of column lines CL intersect. Each of the first synaptic cells SC may include a resistive memory cell. In detail, each of the first synaptic cells SC may include a nonvolatile memory element of a crossbar array. The first synaptic array 110 may store data in the first synaptic cells SC by using a resistance change of a resistive element included in each of the resistive memory cells.

In addition, the first synaptic cells SC may be coupled to the row control circuit 120 through the row lines RL. The first synaptic cells SC may output a plurality of read currents Isig1 to Isigm to the column lines CL, respectively, which correspond to electrical pulse signals applied from the row control circuit 120 through the row lines RL. The first synaptic array 110 may have a configuration as described in FIGS. 1A to 3B. In this case, data stored in the first synaptic array 110 may be learned weights included in a number of layers constituting the neural network system, and the pulse signals and read currents Isig1 to Isigm may represent a result of a multiplication and accumulation computation performed by the neural network system.

The second synaptic array 112 may include a plurality of second synaptic cells SC_R disposed in an area where the row lines RL and two or more reference column lines CL_R intersect. In particular, in an embodiment, the reference column lines CL_R may be provided in an even number. Although FIG. 4 illustrates a case in which two reference column lines CL_R are disposed, the present invention is not limited thereto, and two or more even number of reference column lines CL_R may be disposed.

Each of the second synaptic cells SC_R may include a resistive memory cell. In detail, each of the second synaptic cells SC_R may include a nonvolatile memory element of a crossbar array. In an embodiment, each of the second synaptic cells SC_R may contain substantially the same resistive material as the first synaptic cells SC. In addition, the second synaptic cells SC_R may be coupled to the row control circuit 120 through the row lines RL. The second synaptic cells SC_R may output first and second reference read currents Iref1 and Iref2 to the reference column lines CL_R, respectively, which correspond to pulse signals applied from the row control circuit 120 through the row lines RL.

In this case, all of the second synaptic cells SC_R coupled to the same reference column line among the reference column lines CL_R may be programmed in a high resistance state (HRS), or in a low resistance state (LRS). For example, among the reference column lines CL_R, all of the second synaptic cells SC_R coupled to an odd-numbered reference column line may be programmed in a high-resistance state (HRS), and all of the second synaptic cells SC_R coupled to an even-numbered reference column line may be is programmed in a low-resistance state (LRS). Alternatively, among the reference column lines CL_R, all of the second synaptic cells SC_R coupled to the odd-numbered reference column line may be programmed in a low-resistance state (LRS), and all of the second synaptic cells SC_R coupled to the even-numbered reference column line may be programmed in a high-resistance state (HRS). Accordingly, half of the reference column lines CL_R may output a reference read current corresponding to a high resistance state (HRS), and the other half may output a reference read current corresponding to a low resistance state (LRS).

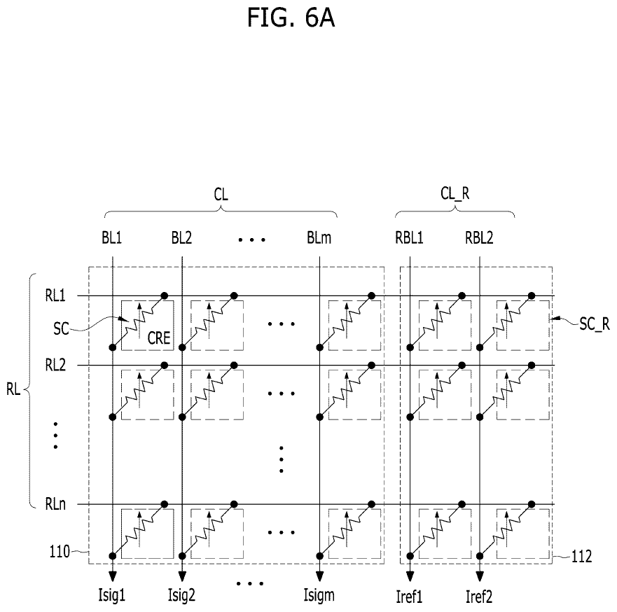

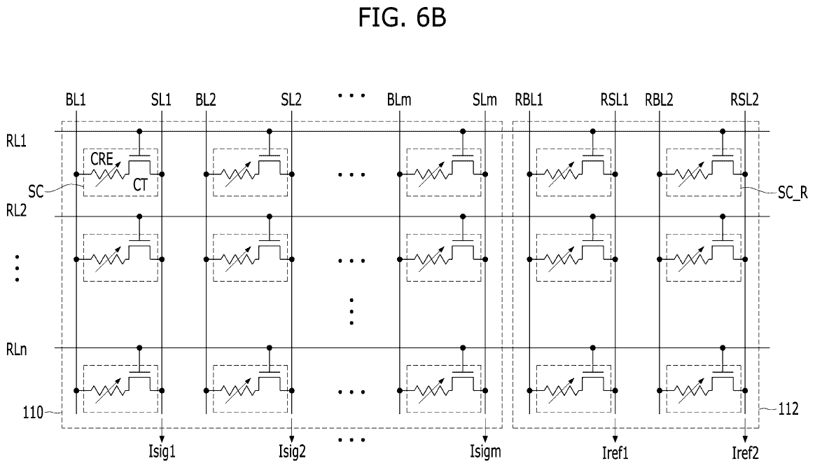

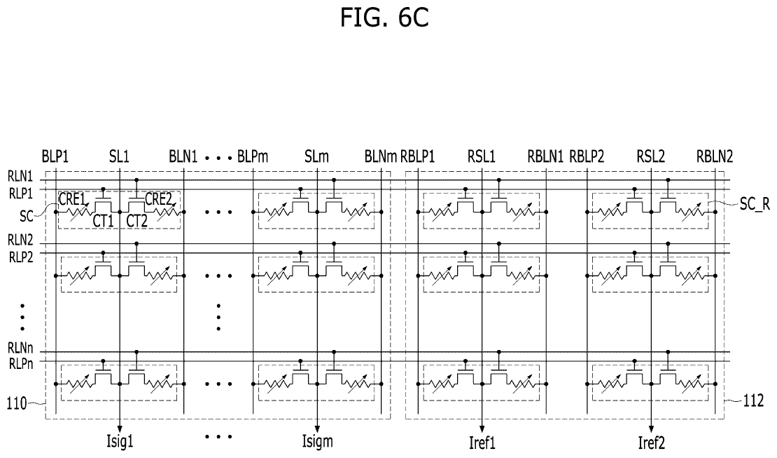

The first synaptic array 110 and the second synaptic array 112 may be disposed adjacent to each other in a row direction. The first synaptic array 110 and the second synaptic array 112 may share the row lines RL. That is, a plurality of first synaptic cells SC and one or more second synaptic cells SC_R may be coupled to one row line. The first synaptic cells SC and the second synaptic cells SC_R coupled to one row line may receive the same pulse signal. That is, in an embodiment, since the second synaptic cells SC_R receive the pulse signal through the same row line RL as the first synaptic cells SC, the second synaptic cells SC_R may simulate the characteristics of the first synaptic cells SC. A detailed configuration of the first synaptic array 110 and the second synaptic array 112 will be described with reference to FIGS. 6A to 8.

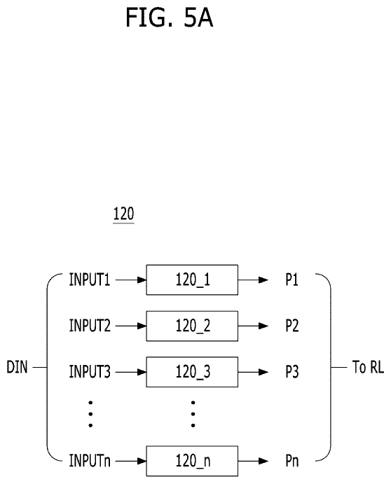

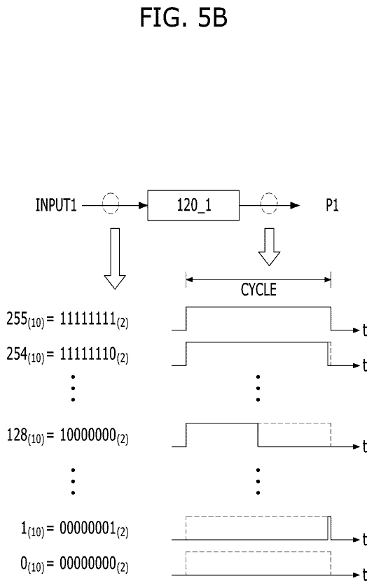

The row control circuit 120 may receive pixel data DIN of an input feature map, convert it into electrical pulse signals, and apply the pulse signals to the row lines RL, respectively. For example, the row control circuit 120 may convert the pixel data DIN in the form of a digital signal into the electrical pulse signals in the form of an analog signal using a digital-to-analog converter (DAC). The row control circuit 120 may drive the row lines RL so that at least one row line selected from the row lines RL is activated according to the pixel data DIN. A detailed configuration and operation of the row control circuit 120 will be described with reference to FIGS. 5A and 5B.

The control logic 150 may provide a column selection signal CS to the column control circuit 130 in response to a control signal CTRL. The control signal CTRL is a signal for selecting a column line from the column lines CL, and may be provided in the form of a column address or the like. The control logic 150 may decode the control signal CTRL to generate the column selection signal CS.

The column control circuit 130 may convert the read currents Isig1 to Isigm in the form of an analog signal, into digital data DOUT by using an analog-to-digital converter (ADC). In particular, in an embodiment, the column control circuit 130 may compensate for the read currents Isig1 to Isigm output through the column lines CL, based on the first and second reference read currents Iref1 and Iref2 output through the reference column lines CL_R, and output the digital data DOUT. In the CiM device 100, since all synaptic cells coupled to one column line are simultaneously read, the effect of the voltage drop caused by the parasitic components of the column lines is greater than that of conventional memory cells for single bit reading. Therefore, in an embodiment, the voltage drop of the column lines CL may be simulated using two or more reference column lines CL_R, and the voltage drop (i.e., offset of the read currents) due to the parasitic component of the column lines CL may be compensated based on the amount of the simulated voltage drop.

In detail, the column control circuit 130 may include a column selection circuit 132, an analog-digital converting circuit 134, and an output circuit 136.

The column selection circuit 132 may select at least one column line from the column lines CL according to the column selection signal CS. For example, the column selection circuit 132 may select k column lines from m column lines CL based on the column selection signal CS, and transmit the read currents output through the selected column lines to the analog-digital converting circuit 134. The column selection signal CS may be a signal composed of multi-bits. For example, the column selection circuit 132 may include a plurality of switches respectively coupled to the column lines CL. Each of the switches may be turned on according to a corresponding bit of the column selection signal CS to transmit a read current from a corresponding column line to the analog-digital converting circuit 134.

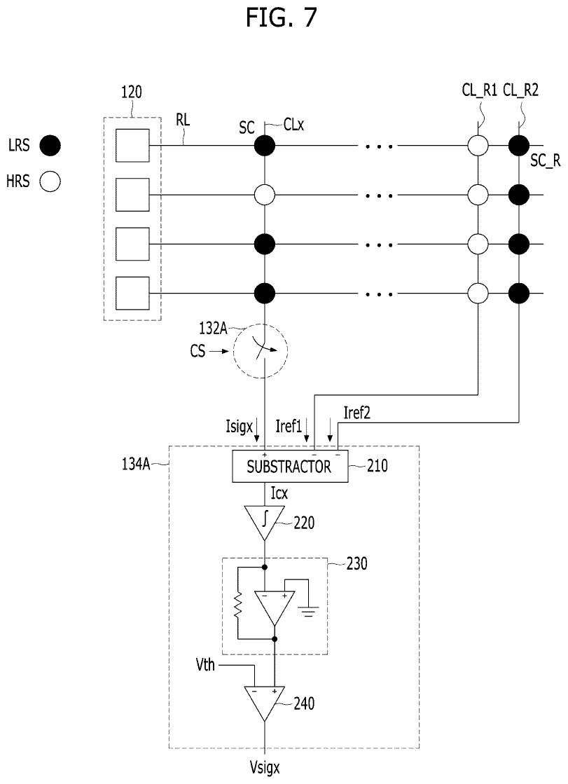

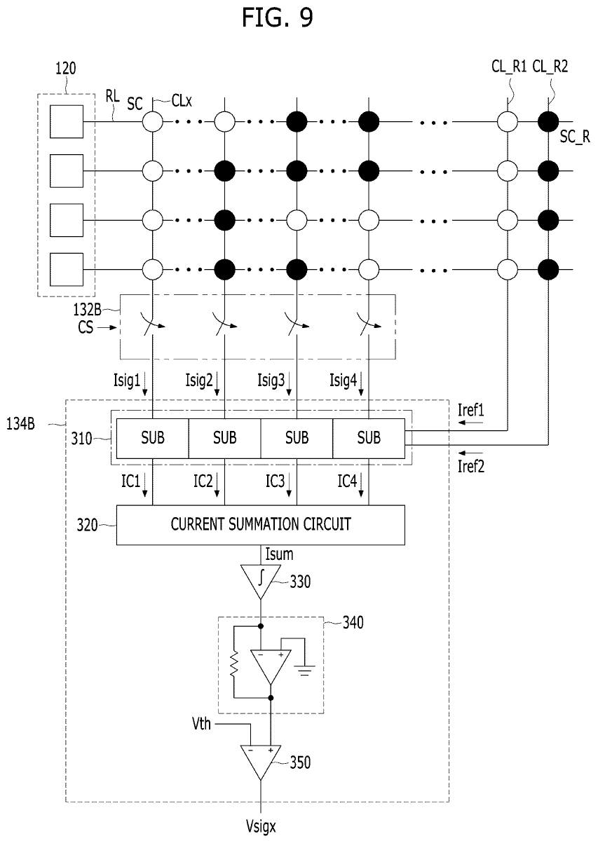

The analog-digital converting circuit 134 may compensate for offsets of the read currents Isig1 to Isigm transmitted from the column selection circuit 132, based on the first and second reference read currents Iref1 and Iref2. For example, the analog-digital converting circuit 134 may subtract the first and second reference read currents Iref1 and Iref2 from each of the read currents Isig1 to Isigm. According to an embodiment, the analog-digital converting circuit 134 may calculate an average value of the reference read currents Iref1 and Iref2 and generate a replica current by reflecting a specific weight on the average value. The analog-digital converting circuit 134 may generate a plurality of compensated read currents by subtracting the replica current from each of the read currents Isig1 to Isigm, and convert and output the compensated read currents into a read voltage-level signals Vsig1 to Vsigm in the form of a digital signal. The analog-digital converting circuit 134 may include a plurality of analog-to-digital converters (ADC) which are coupled to the switches of the column selection circuit 132 and output the read voltage-level signals Vsig1 to Vsigm, respectively. A detailed configuration and operation of the analog-digital converting circuit 134 will be described with reference to FIGS. 7 and 9.

The output circuit 136 may apply an activation function onto the read voltage-level signals Vsig1 to Vsigm provided from the analog-digital converting circuit 134. The activation function may be performed by using Sigmoid, Tanh, and ReLU (Rectified Linear Unit) functions, but the activation function is not limited thereto, and various activation functions may be applied. The output circuit 136 may output the digital data DOUT by performing a multiplication and accumulation computation on the read voltage-level signals Vsig1 to Vsigm to which the activation function is applied.

Moreover, when the CiM device 100 of FIG. 4 is implemented with a neuromorphic device, the row control circuit 120 may include a plurality of pre-synaptic neurons (20 described in FIG. 2A), and the column control circuit 130 may include a plurality of post-synaptic neurons (30 described in FIG. 2A). In addition, although FIG. 4 illustrates a case in which the CiM device 100 includes one crossbar array circuit, the present invention is not limited thereto, and a plurality of crossbar array circuits may be connected and arranged. In this case, the digital data DOUT output from the output circuit 136 may be used as pixel data DIN of an input feature map of another crossbar array circuit. When the digital data DOUT to which the activation function is applied is used as the pixel data DIN of the input feature map of another crossbar array circuit, the above-described process may be applied equally to other crossbar array circuits.

FIGS. 5A and 5B are a block diagram and a timing diagram illustrating the row control circuit 120 of FIG. 4 in accordance with an embodiment of the present invention.

Referring to FIG. 5A, the row control circuit 120 may include a plurality of pulse conversion circuits 120_1 to 120_n corresponding to the row lines RL, as a form of DAC. The pulse conversion circuits 120_1 to 120_n may correspond to the pre-synaptic neurons 20 of FIG. 2A. The pulse conversion circuits 120_1 to 120_n may generate a plurality of pulse signals P1 to Pn having a width or amplitude of an electrical pulse determined according to the corresponding input data INPUT1 to INPUTn in the pixel data DIN, and may apply the pulse signals P1 to Pn to the row lines RL. Each of the pulse conversion circuits 120_1 to 120_n may be implemented with a pulse width modulator (PWM) for generating the pulse signals according to the width, or a pulse amplitude modulator (PAM) for generating the pulse signals according to the amplitude.

Referring to FIG. 5B, a case in which the first pulse conversion circuit 120_1 is implemented as a pulse width modulator (PWM) is illustrated. The input data INPUT1 may be composed of binary data (e.g., 8-bit binary data). The first pulse conversion circuit 120_1 may determine a pulse width of the pulse signal P1 based on the binary input data INPUT1. For example, when the value of the input data INPUT1 is 255, the pulse width of the pulse signal P1 may be maximized during a signal application cycle. Accordingly, a time for which the pulse signal P1 is applied may be maximized. As the value of the input data INPUT1 becomes less than 255, the pulse width of the pulse signal P1 may gradually decrease during the signal application cycle. That is, as the value of the input data INPUT1 decreases, the time for which the pulse signal P1 is applied may decrease.

In this way, the pulse conversion circuits 120_0 to 120_n may convert the pixel data DIN in the form of a digital signal into the pulse signals P1 to Pn in the form of an analog signal, and apply the pulse signals P1 to Pn to the row lines RL.

FIGS. 6A to 6C are diagrams for describing the first synaptic array 110 and the second synaptic array 112 in accordance with an embodiment of the present invention.

Referring to FIG. 6A, the first synaptic array 110 may include a plurality of first synaptic cells SC disposed in an area where n row lines RL1 to RLn and m column lines (hereinafter, bit lines BL1 to BLm) intersect. The second synaptic array 112 may include a plurality of second synaptic cells SC_R disposed in an area where the n row lines RL1 to RLn and two reference column lines (hereinafter, first and second reference bit lines RBL1 and RBL2) intersect. The first synaptic cells SC and the second synaptic cells SC_R

may have substantially the same configuration. For example, each of the first synaptic cells SC and the second synaptic cells SC_R may be configured as a resistive memory cell having two terminals. That is, each resistive memory cell may include a variable resistance element CRE coupled between a corresponding row line and a corresponding bit line. The variable resistance element CRE may change a resistance value by a voltage applied through the row lines RL1 to RLn and/or the bit lines BL1 to BLm, RBL1, and RBL2, and the first synaptic cells SC and the second synaptic cells SC_R may store data by such a resistance change. For example, when a certain level of a write pulse signal is applied to a selected row line and a ground voltage (e.g., about 0V) is applied to a selected bit line, high data ‘1’ may be written to a selected resistive memory cell. For example, when a write pulse signal is applied to the selected row line and a certain level of a write voltage is applied to the selected bit line, low data ‘0’ may be written to the selected resistive memory cell. Further, when a predetermined level of read voltage is applied to the selected row line and a ground voltage is applied to the selected bit line, written data may be read from the selected resistive memory cell.

In an embodiment, each of the resistive memory cells may include any resistive memory cell such as a phase change random access memory (PRAM) cell, a resistive random access memory (RRAM) cell, a magnetic random access memory (MRAM) cell, and a ferroelectric random access memory (FRAM) cell. In an embodiment, the variable resistance element CRE may have a phase-change material whose crystal state changes according to the amount of current flowing. In another embodiment, the variable resistance element CRE may have a single-layer structure or a multilayer structure including a transition metal oxide, a metal oxide such as a perovskite-based material, a chalcogenide-based material, a ferroelectric material, a ferromagnetic material, and the like. However, a resistive material included in the variable resistance element CRE is not limited to the aforementioned materials.

The first synaptic cells SC may correspond to one synapse or a connection of a neural network system, and may store weights. Accordingly, the n*m data stored in the first synaptic array 110 may correspond to weights implemented in the form of the n*m matrix W 52 of FIGS. 3A and 3B. That is, the read currents Isig1 to Isigm output through m bit lines BL1 to BLm may correspond to the current 63 output from the n*m matrix W 52, which is the result of the multiplication between the voltage 61 and the conductance 62. In the first synaptic array 110 where the weights in the form of a matrix are stored in the first synaptic cells SC, when the pulse signals corresponding to the pixel data of the input feature map are input through the row lines RL1 to RLn, the read currents Isig1 to Isigm output through the bit lines BL1 to BLm may be a result of multiplication and accumulation computation performed by the neural network system. By implementing all of the multiple layers of the neural network system in this way, a CiM device that performs data storage and computation operations at once may be implemented.

In an embodiment, all of the second synaptic cells SC_R coupled to the same reference bit line may be programmed in a high resistance state (HRS) or a low resistance state (LRS). For example, all of the second synaptic cells SC_R coupled to the first reference bit line RBL1 may be programmed in a high resistance state (HRS), and all of the second synaptic cells SC_R connected to the second reference bit line RBL2 may be programmed in a low resistance state is (LRS). Accordingly, the first reference read current Iref1 output from the first reference bit line RBL1 may have a current amount corresponding to the high resistance state (HRS), and the second reference read current Iref2 output from the second reference bit line RBL2 may have a current amount corresponding to the low resistance state (LRS).

Referring to FIG. 6B, the column lines CL may include m bit lines BL1 to BLm and m source lines SL1 to SLm, and the reference column lines CL_R may include first and second reference bit lines RBL1 and RBL2, and first and second reference source lines RSL1 and RSL2. In this case, the column control circuit 130 of FIG. 4 may further include a driving circuit (not shown) for driving the bit lines BL1 to BLm and the first and second reference bit lines RBL1 and RBL2.

The first synaptic array 110 may include a plurality of first synaptic cells SC disposed in an area where n row lines RL1 to RLn intersect with m bit lines BL1 to BLm and m SL1 to SLm. The second synaptic array 112 may include a plurality of second synaptic cells SC_R disposed in an area where the n row lines RL1 to RLn intersect with the first and second reference bit lines RBL1 and RBL2 and the first and second reference source lines RSL1 and RSL2.

The first synaptic cells SC and the second synaptic cells SC_R may have substantially the same configuration. For example, each of the first synaptic cells SC and the second synaptic cells SC_R may be configured as a resistive memory cell having three terminals. That is, each resistive memory cell may include a cell transistor CT and a variable resistance element CRE, which are coupled between a corresponding row line, a corresponding bit line, and a corresponding source line. The cell transistor CT may include a first electrode coupled to the corresponding source line, a gate electrode coupled to the corresponding row line, and a second electrode and the variable resistance element CRE may be coupled between the second electrode of the cell transistor CT and the corresponding bit line. The variable resistance element CRE may have substantially the same configuration as the variable resistance element CRE of FIG. 6A.

When a certain level of a write pulse signal is applied to a selected row line, a write voltage is applied to a selected bit line, and a ground voltage (e.g., about 0V) is applied to a selected source line, high data ‘1’ may be written to the selected resistive memory cell.

When a write pulse signal is applied to the selected row line, a ground voltage is applied to the selected bit line, and a write voltage is applied to the selected source line, low data ‘0’ may be written to the selected resistive memory cell. Further, when a predetermined level of read voltage is applied to the selected row line, a read voltage is applied to the selected bit line, and a ground voltage is applied to the selected source line, written data may be read from the selected resistive memory cell.

The first synaptic array 110 may output the read currents Isig1 to Isigm through electrical paths including m bit lines BL1 to BLm. For example, the first synaptic array 110 may output the first read current Isig1 flowing from the first bit line BL1 and to the first source line SL1, may output the second read current Isig2 flowing from the second bit line BL2 and to the second source line SL2, and, in this way, may output the m-th read current Isigm flowing from the m-th bit line BLm and to the m-th source line SLm.

Similarly, the second synaptic array 112 may output the first and second reference read currents Iref1 and Iref2 through electrical paths including the first and second reference bit lines RBL1 and RBL2. For example, the second synaptic array 112 may output the first reference read current Iref1 flowing from the first reference bit line RBL1 to the first reference source line RSL1, and may output the second reference read current Iref2 flowing from the second reference bit line RBL2 to the second reference source line RSL2. In an embodiment, all of the variable resistance elements CRE of the second synaptic cells SC_R coupled to the same reference bit line may be programmed in a high resistance state (HRS) or in a low resistance state (LRS).

Referring to FIG. 6C, the row lines RL may be composed of a plurality of positive row lines RLP1 to RLPn and a plurality of negative row lines RLN1 to RLNn. The column lines CL may include m bit lines BL1 to BLm and m source lines SL1 to SLm, and m bit lines BL1 to BLm may be composed of positive bit lines BLP1 to BLPm and negative bit lines BLN1 to BLNm. The reference column lines CL_R may include first and second reference bit lines RBL1 and RBL2 and first and second reference source lines RSL1 and RSL2, and the first and second reference bit lines RBL1 and RBL2 may be composed of a plurality of positive reference bit lines RBLP1 and RBLP2 and a plurality of negative reference bit lines RBLN1 and RBLN2. In this case, the column control circuit 130 of FIG. 4 may further include a driving circuit (not shown) for driving the positive bit lines BLP1 to BLPm, the negative bit lines BLN1 to BLNm, the positive reference bit lines RBLP1 and RBLP2, and the negative reference bit lines RBLN1 and RBLN2.

The first synaptic cells SC and the second synaptic cells SC_R may have substantially the same configuration. For example, each of the first synaptic cells SC and the second synaptic cells SC_R may be configured as a resistive memory cell having a 2T2R structure consisting of two transistors and two resistive elements. That is, each resistive memory cell may include a first cell transistor CT1 and a first variable resistance element CRE1, which are coupled between a corresponding positive row line, a corresponding positive bit line, and a corresponding source line, and a second cell transistor CT2 and a second variable resistance element CRE2, which are coupled between a corresponding negative row line, a corresponding negative bit line, and the corresponding source line. For example, the first cell transistor CT1 may include a first electrode coupled to the corresponding source line SL1, a gate electrode coupled to the positive row line RLP1, and a second electrode, and the first variable resistance element CRE1 may be coupled between the corresponding positive bit line BLP1 and the second electrode of the first cell transistor CT1. The second cell transistor CT2 may include a third electrode coupled to the corresponding source line SL1, a gate electrode coupled to the negative row line RLN1, and a fourth electrode, and the second variable resistance element CRE2 may be coupled between the corresponding negative bit line BLN1 and the fourth electrode of the second cell transistor CT2. The first variable resistance element CRE1 and the second variable resistance element CRE2 may have substantially the same configuration as the variable resistance element CRE of FIG. 6A. The write operation and the read operation may be performed in the same manner as described in FIG. 6B.

The first synaptic array 110 may output the read currents Isig1 to Isigm through electrical paths that include the positive bit lines BLP1 to BLPm and the negative bit lines BLN1 to BLNm. For example, when a pulse signal is applied to the first positive row line RLP1 and the first negative row line RLN1, and different voltages are applied to the first positive bit line BLP1 and the first negative bit line BLN1, the first synaptic array 110 may output the first read current Isig1 flowing from the first positive bit line BLP1 and the first negative bit line BLN1 to the first source line SL1 in common. At this time, the first read current Isig1 may be formed to correspond to a voltage difference between the first positive bit line BLP1 and the first negative bit line BLN1.

Similarly, the second synaptic array 112 may output the first and second reference read currents Iref1 and Iref2 through electrical paths including the positive reference bit lines RBLP1 and RBLP2 and the negative reference bit lines RBLN1 and RBLN2. For example, the second synaptic array 112 may output the first read current Iref1 flowing from the first positive reference bit line RBLP1 and the first negative reference bit line RBLN1 to the first reference source line RSL1 in common, and may output the second read current Isig2 flowing from the second reference bit line RBL2 to the second reference source line RSL2 in common. In an embodiment, all of the variable resistance elements CRE of the second synaptic cells SC_R coupled to the same reference bit line may be programmed in a high resistance state (HRS) or in a low resistance state (LRS).

FIG. 7 is a circuit diagram illustrating the column control circuit 130 of FIG. 4 in accordance with an embodiment of the present invention. In FIG. 7, a case in which two reference column lines CL_R are disposed in the second synaptic array 112, and one column line CLx is selected according to the column selection signal CS, is shown.

Referring to FIG. 7, a switch 132A of the column selection circuit 132 may be turned on to select one column line CLx from the column lines CL according to the column selection signal CS.

An ADC 134A of the analog-digital converting circuit 134 may include a subtractor 210, an integrator 220, a trans-impedance amplifier (TIA) 230, and a comparator 240. The ADC 134A illustrated in FIG. 7 may be arranged in the number corresponding to the column lines CL.

The subtractor 210 may calculate a current difference between the read current Isigx and the first and second reference read currents Iref1 and Iref2. The subtractor 210 may subtract the first and second reference read currents Iref1 and Iref2 from the read current Isigx. For example, the subtractor 210 may calculate an average value of the first and second reference read currents Iref1 and Iref2 and may generate a replica current by reflecting a specific weight on the average value. Preferably, the specific weight may be a value between 0 and 1. For example, the specific weight may be set to 0.1. The subtractor 210 may compensate for an offset of the read current Isigx due to the parasitic component of the column line CLx by subtracting the replica current from the read current Isigx.

The integrator 220 may integrate an output current Icx of the subtractor 210. The integrator 220 may integrate, sum, or accumulate at least a portion of the output current Icx of the subtractor 210. The integrator 220 may be implemented as a known integrator.

The TIA 230 may convert and amplify an output current of the integrator 220 into a voltage signal. For example, the TIA 230 may be implemented with an operational amplifier in which a positive input terminal (+) is connected to a ground voltage terminal and a negative input terminal (−) is connected to an output terminal through a resistor. The output current of the integrator 220 may be applied to the negative input terminal (−) of the TIA 230.

The comparator 240 may convert and output a read voltage-level signal Vsigx corresponding to the voltage signal of the TIA 230 based on a reference voltage Vth. The comparator 240 may output the read voltage-level signal Vsigx in the form of a digital signal according to a result of comparing the reference voltage Vth with the voltage signal of the TIA 230. For example, when the voltage signal of the TIA 230 is greater than or equal to the reference voltage Vth, the comparator 240 may output the read voltage-level signal Vsigx having a logic high level.

As described above, in an embodiment, an even number of reference column lines CL_R are arranged, and all of the second synaptic cells SC_R coupled to the odd-numbered reference column line are programmed in a high resistance state (HRS) while all of the second synaptic cells SC_R coupled to the even-numbered reference column line are programmed in a low resistance state (LRS). As a result, the first reference read current Iref1 having a current amount corresponding to the high resistance state (HRS) and the second reference read current Iref2 having a current amount corresponding to the low resistance state (LRS) may be read from the second synaptic array 112. Further, the voltage drop of the column lines CL may be simulated using the average value of the first and second reference read currents Iref1 and Iref2, and the amount of the simulated voltage drop may be used to compensate for the voltage drop due to the parasitic component of the column lines CL. Therefore, it is possible to prevent the accuracy of inference of the CiM device and increase reliability by compensating for the voltage drop of the column lines CL while reducing dependence on process, voltage and temperature (PVT).

Recently, a method of inferring one pixel data through two or more synaptic cells has been proposed to improve the recognition rate of pixel data in an input feature map.

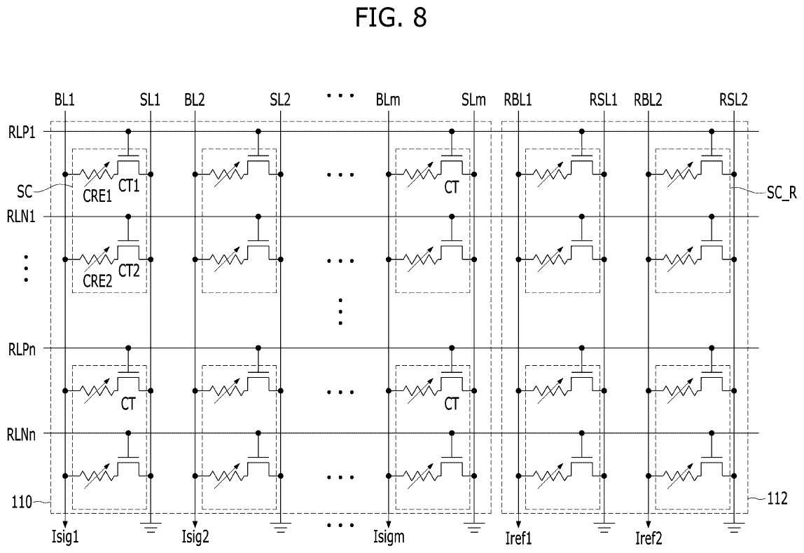

FIG. 8 is a diagram for describing the first synaptic array 110 and the second synaptic array 112 in accordance with another embodiment of the present invention

Referring to FIG. 8, the row lines RL may be composed of a plurality of positive row lines RLP1 to RLPn and a plurality of negative row lines RLN1 to RLNn. The column lines CL may include m bit lines BL1 to BLm and m source lines SL1 to SLm. The reference column lines CL_R may include first and second reference bit lines RBL1 and RBL2 and first and second reference source lines RSL1 and RSL2. In FIG. 8, m source lines SL1 to SLm and the first and second reference source lines RSL1 and RSL2 are coupled to a ground voltage terminal.

The first synaptic cells SC and the second synaptic cells SC_R may have substantially the same configuration. For example, each of the first synaptic cells SC and the second synaptic cells SC_R may be configured as a resistive memory cell having a 2T2R structure consisting of two transistors and two resistive elements. That is, each resistive memory cell may include a first cell transistor CT1 and a first variable resistance element CRE1, which are coupled between a corresponding positive row line, a corresponding bit line, and a corresponding source line, and a second cell transistor CT2 and a second variable resistance element CRE2, which are coupled between a corresponding negative row line, the corresponding bit line, and the corresponding source line. For example, the first cell transistor CT1 may include a first electrode coupled to the corresponding source line SL1, a gate electrode coupled to the positive row line RLP1, and a second electrode, and the first variable resistance element CRE1 may be coupled between the corresponding bit line BL1 and the second electrode of the first cell transistor CT1. The second cell transistor CT2 may include a third electrode coupled to the corresponding source line SL1, a gate electrode coupled to the negative row line RLN1, and a fourth electrode and the second variable resistance element CRE2 may be coupled between the corresponding bit line BL1 and the fourth electrode of the second cell transistor CT2. The first variable resistance element CRE1 and the second variable resistance element CRE2 may have substantially the same configuration as the variable resistance element CRE of FIG. 6A. The write operation and the read operation may be performed in the same manner as described in FIG. 6B.

The first synaptic array 110 may output the read currents Isig1 to Isigm through electrical paths that include the bit lines BL1 to BLm. For example, when a pulse signal is applied to the first positive row line RLP1 and the first negative row line RLN1, and a certain level of a write voltage is applied to the first bit line BL1, the first synaptic array 110 may output the first read current Isig1 flowing from the first source line SL1 to the first bit line BL1. At this time, signals applied to the first positive row line RLP1 and the first negative row line RLN1 may have complementary levels.

For example, a pulse signal of a logic high level may be applied to the first positive row line RLP1 while a pulse signal of a logic low level may be applied to the first negative row line RLN1. Depending on weights (i.e., the conductance) of the first variable resistance element CRE1 and the second variable resistance element CRE2, the first read current Isig1 may be output as various (+) values. On the other hand, a pulse signal of a logic low level may be applied to the first positive row line RLP1 while a pulse signal of a logic high level may be applied to the first negative row line RLN1. Depending on weights (i.e., the conductance) of the first variable resistance element CRE1 and the second variable resistance element CRE2, the first read current Isig1 may be output as various (−) values. In this way, a cell structure that outputs a read current corresponding to stored weights according to pulse signals applied to two adjacent row lines is called a 2-bit weight cell structure.

Similarly, the second synaptic array 112 may output the first and second reference read currents Iref1 and Iref2 through electrical paths including the reference bit lines RBL1 and RBL2. For example, the second synaptic array 112 may output the first read current Iref1 flowing from the first reference source line RSL1 to the first reference bit line RBL, and may output the second read current Isig2 flowing from the second reference source line RSL2 to the second reference bit line RBL2. Likewise, depending on weights (i.e., the conductance) of the first variable resistance element CRE1 and the second variable resistance element CRE2, the first and second reference read currents Iref1 and Iref2 may be output as various (+) or (−) values.

In an embodiment, all of the variable resistance elements CRE of the second synaptic cells SC_R connected to the same reference bit line may be programmed in a high resistance state (HRS) or in a low resistance state (LRS). Accordingly, the first reference read current Iref1 output from the first reference source line RSL1 may have a current amount corresponding to the high resistance state (HRS), and the second reference read current Iref2 output from the second reference source line RSL2 may have a current amount corresponding to the low resistance state (LRS).

In the 2-bit weight cell structure of FIG. 8, two or more of a plurality of bit lines BL1 to BLm of the first synaptic array 110 may share one ADC.

FIG. 9 is a circuit diagram illustrating the column control circuit 130 of FIG. 4 in accordance with another embodiment of the present invention. In FIG. 9, a case in which two reference column lines CL_R are disposed in the second synaptic array 112, and first to fourth read currents Isig1 to Isig4 are sequentially output through 4 column lines CLx selected according to the column selection signal CS, is shown.

Referring to FIG. 9, 4 switches 132B of the column selection circuit 132 may be sequentially turned on to sequentially select 4 column lines CLx from the column lines CL according to the column selection signal CS.

An ADC 134B of the analog-digital converting circuit 134 may include 4 subtractors 310, a current summation circuit 320, an integrator 330, a trans-impedance amplifier (TIA) 340, and a comparator 350. The ADC 134B illustrated in FIG. 9 may be shared by 4 column lines CLx.

The subtractors 310 may calculate a current difference between the first to fourth read currents Isig1 to Isig4 and the first and second reference read currents Iref1 and Iref2. Each of the subtractors 310 may subtract the first and second reference read currents Iref1 and Iref2 from a corresponding one of the first to fourth read currents Isig1 to Isig4. For example, the subtractors 310 may calculate an average value of the first and second reference read currents Iref1 and Iref2 and may generate a replica current by reflecting a specific weight on the average value. Preferably, the specific weight may be a value between 0 and 1. For example, the specific weight may be set to 0.1. Each of the subtractors 310 may compensate for an offset of the corresponding read current due to the parasitic component of a corresponding one of 4 column lines CLx by subtracting the replica current from the corresponding read current.

The current summation circuit 320 may generate a summation current Isum by summing first to fourth output currents Ic1 to Ic4 of the subtractors 310.

The integrator 330 may integrate the summation current Isum of the current summation circuit 320. The integrator 330 may integrate, sum, or accumulate at least a portion of the summation current Isum of the current summation circuit 320. The integrator 330 may be implemented as a known integrator.

The TIA 340 may convert and amplify an output current of the integrator 330 into a voltage signal. For example, the TIA 340 may be implemented with an operational amplifier in which a positive input terminal (+) is connected to a ground voltage terminal and a negative input terminal (−) is connected to an output terminal through a resistor. The output current of the integrator 330 may be applied to the negative input terminal (−) of the TIA 340.

The comparator 350 may convert and output a read voltage-level signal Vsigx corresponding to the voltage signal of the TIA 340 based on a reference voltage Vth. The comparator 350 may output the read voltage-level signal Vsigx in the form of a digital signal according to a result of comparing the reference voltage Vth with the voltage signal of the TIA 340.

As described above, in an embodiment, the CiM device having the 2-bit weight cell structure may simulate the voltage drop of the column lines CL using an even number of the reference column lines CL_R, and compensate for the voltage drop due to the parasitic component of the column lines CL by using the simulated amount of the voltage drop. Further, the voltage drop of the column lines CL may be simulated using the average value of the first and second reference read currents Iref1 and Iref2, by reading the first reference read current Iref1 with the current amount corresponding to the high resistance state (HRS) and the second reference read current Iref2 with the current amount corresponding to the low resistance state (LRS). Therefore, it is possible to prevent the accuracy of inference of the CiM device and increase reliability by compensating for the voltage drop of the column lines CL while reducing dependence on PVT.

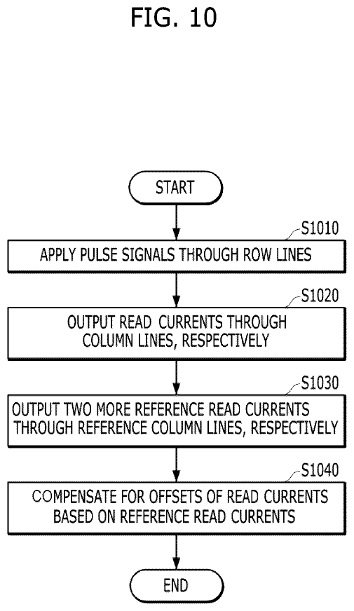

Hereinafter, an operating method of the CiM device according to an embodiment of the present invention will be described with reference to FIGS. 4 and 10.

FIG. 10 is a flowchart illustrating an operating method of a CiM device in accordance with an embodiment of the present invention.

Referring to FIG. 10, the first synaptic array 110 may include the first synaptic cells SC disposed in an area where the column lines CL intersect, and the second synaptic array 112 may include the second synaptic cells SC_R disposed in an area where the row lines RL and two or more reference column lines CL_R intersect. At this time, all of the second synaptic cells SC_R coupled to an odd-numbered reference column line may be programmed in a high-resistance state (HRS), and all of the second synaptic cells SC_R coupled to an even-numbered reference column line may be programmed in a low-resistance state (LRS).

The row control circuit 120 may receive the pixel data DIN of an input feature map, convert it into electrical pulse signals, and apply the pulse signals to the row lines RL. Accordingly, the pulse signals may be applied to the first synaptic cells SC and the second synaptic cells SC_R (at S1010).

The first synaptic cells SC may output the read currents Isig1 to Isigm to the column lines CL, respectively, which correspond to the electrical pulse signals applied from the row control circuit 120 through the row lines RL (at S1020). In addition, the second synaptic cells SC_R may output the first and second reference read currents Iref1 and Iref2 corresponding to the pulse signals through the reference column lines CL_R, respectively (at S1030). At this time, the first reference read current Iref1 output from the first reference bit line RBL1 may have a current amount corresponding to the high resistance state (HRS), and the second reference read current Iref2 output from the second reference bit line RBL2 may have a current amount corresponding to the low resistance state (LRS).

The column control circuit 130 may compensate for the read currents Isig1 to Isigm output through the column lines CL, based on the first and second reference read currents Iref1 and Iref2 output through the reference column lines CL_R, and output the digital data DOUT (at S1040).

In detail, the analog-digital converting circuit 134 may calculate an average value of the reference read currents Iref1 and Iref2, generate a replica current by reflecting a specific weight on the average value, and generate a plurality of compensated read currents by subtracting the replica current from each of the read currents Isig1 to Isigm. The analog-digital converting circuit 134 may convert and output the compensated read currents into a read voltage-level signals Vsig1 to Vsigm in the form of a digital signal. The output circuit 136 may apply an activation function onto the read voltage-level signals Vsig1 to Vsigm provided from the analog-digital converting circuit 134, and output the digital data DOUT by performing a multiplication and accumulation computation on the read voltage-level signals Vsig1 to Vsigm to which the activation function is applied.

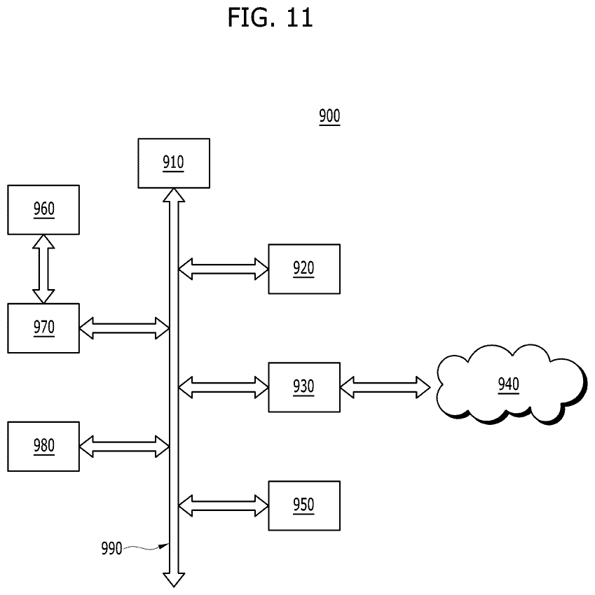

FIG. 11 is a diagram for describing a pattern recognition system 900 including a neuromorphic device in accordance with an embodiment of the present invention.

Referring to FIG. 11, the pattern recognition system 900 may include a central processing unit (CPU) 910, a memory unit 920, a communication control unit 930, a network 940, an output unit 950, an input unit 960, an analog-digital converter (ADC) 970, a neuromorphic unit 980, and/or a bus 990.

For example, the pattern recognition system 900 may include any of a speech recognition system, an imaging recognition system, a code recognition system, a signal recognition system, and one or more systems for recognizing various patterns.

The CPU 910 may generate and transmit various signals for a learning process of the neuromorphic unit 980, and perform various processes and functions for recognizing patterns according to an output from the neuromorphic unit 980. For example, the CPU 910 may perform processes and functions for recognizing speech and imaging patterns based on the output from the neuromorphic unit 980. The CPU 910 may be connected with the memory unit 920, the communication control unit 930, the output unit 950, the ADC 970, and the neuromorphic unit 980 through the bus 990.

The memory unit 920 may store various pieces of information, which are stored in the pattern recognition system 900. The memory unit 920 may include one or more of a volatile memory device, such as a DRAM or SRAM, a nonvolatile memory, such as PRAM, MRAM, ReRAM, or NAND flash memory, and one or more various memory units, such as a Hard Disk Drive (HDD) and a Solid State Drive (SSD).

The communication control unit 930 may transmit and/or receive data to and/or from a communication control unit of another system through the network 940. For example, the communication control unit 930 may transmit speech and/or image recognition data through the network 940.

The output unit 950 may output data in various manners. For example, the output unit 950 may include one or more of a speaker, a printer, a monitor, a display panel, a beam projector, a hologrammer, or other various output devices. The output unit 950 may output, for example, speech and/or image recognition data.

The input unit 960 may include one or more of a microphone, a camera, a scanner, a touch pad, a keyboard, a mouse, a mouse pen, or one or more of various sensors.

The ADC 970 may convert analog data inputted from the input unit 960 into digital data.

The neuromorphic unit 980 may perform learning or recognition using the data outputted from the ADC 970, and output data corresponding to recognized patterns. The neuromorphic unit 980 may include one or more of the neuromorphic devices in accordance with the various embodiments described above.

Various embodiments of the present disclosure have been described in the drawings and specification. Although specific terminologies are used here, the terminologies are only to describe the embodiments of the present disclosure. Therefore, the present disclosure is not restricted to the above-described embodiments and many variations are possible within the spirit and scope of the present disclosure. It should be apparent to those skilled in the art that various modifications can be made based on the technological scope of the present disclosure in addition to the embodiments disclosed herein. The embodiments may be combined to form additional embodiments

It should be noted that although the technical spirit of this disclosure has been described in connection with embodiments thereof, this is merely for description purposes and should not be interpreted as limiting. It should be appreciated by one of ordinary skill in the art that various changes may be made thereto without departing from the technical spirit of this disclosure and the following claims.

For example, for the logic gates and transistors provided as examples in the above-described embodiments, different positions and types may be implemented depending on the polarity of the input signal. Furthermore, the embodiments may be combined to form additional embodiments.

What is claimed is:

1. A Computation-in-Memory (CiM) device comprising:
a plurality of first synaptic cells disposed between a plurality of row lines and a plurality of column lines and configured to output a plurality of read currents to the column lines, the read currents corresponding to pulse signals applied through the row lines;
a plurality of second synaptic cells disposed between the row lines and two or more reference column lines and configured to output two or more reference read currents to the reference column lines, the reference read currents corresponding to the pulse signals applied through the row lines; and
a column control circuit configured to output digital data by compensating for the read currents output through the column lines, based on the reference read currents output through the reference column lines.

2. The CiM device of claim 1,
wherein the reference column lines are provided in an even number, and
wherein all of the second synaptic cells coupled to an odd-numbered reference column line are programmed in a high-resistance state (HRS) and all of the second synaptic cells coupled to an even-numbered reference column line are programmed in a low-resistance state (LRS).

3. The CiM device of claim 1, wherein the column control circuit is configured to compensate for the read currents by:
generating a replica current by reflecting a specific weight on an average value of the reference read currents, and
compensating for offsets of the read currents by subtracting the replica current from the read currents.

4. The CiM device of claim 1, wherein the column control circuit includes a plurality of analog-to-digital converters (ADCs) corresponding to the respective column lines.

5. The CiM device of claim 4, wherein each of the ADCs includes:
a subtractor configured to generate a replica current by reflecting a specific weight on an average value of the reference read currents and configured to subtract the replica current from a corresponding read current;
an integrator configured to integrate an output current of the subtractor; and
a comparator configured to output the digital data corresponding to an output current of the integrator based on a reference voltage.

6. The CiM device of claim 5, wherein each of the ADCs further includes a trans-impedance amplifier (TIA) configured to convert and amplify the output current of the integrator into a voltage signal and configured to provide the voltage signal to the comparator.

7. The CiM device of claim 4, wherein each of the second synaptic cells has substantially the same configuration as each of the first synaptic cells.

8. The CiM device of claim 7, wherein each of the first synaptic cells includes a variable resistance element coupled between a corresponding row line and a corresponding column line.

9. The CiM device of claim 7,
wherein each of the first synaptic cells includes:
a cell transistor configured to have a first electrode coupled to a source line of the corresponding column line, a gate electrode coupled to the corresponding row line, and a second electrode; and
a variable resistance element coupled between the second electrode of the cell transistor and a bit line of the corresponding column line, and
wherein a corresponding read current is output through the source line.

10. The CiM device of claim 7,
wherein each of the first synaptic cells includes:
a first cell transistor having a first electrode coupled to a source line of the corresponding column line, a gate electrode coupled to a positive row line, and a second electrode;
a first variable resistance element coupled between a positive bit line of the corresponding column line and the second electrode;
a second cell transistor having a third electrode coupled to the source line, a gate electrode coupled to a negative row line, and a fourth electrode; and
a second variable resistance element coupled between a negative bit line of the corresponding column line and the fourth electrode, and
wherein a corresponding read current is output through the source line.

11. The CiM device of claim 1, wherein the column control circuit includes:
a plurality of analog-to-digital converters (ADCs) each shared by two or more selected column lines; and
a column selection circuit configured to sequentially transfer, to the ADCs, the read currents output through the selected column lines.

12. The CiM device of claim 4, wherein each of the ADCs includes:
subtractors each configured to generate a replica current by reflecting a specific weight on an average value of the reference read currents and to subtract the replica current from a corresponding read current output through the selected column lines;
a current summation circuit configured to generate a summation current by summing output currents of the subtractors;
an integrator configured to integrate the summation current; and
a comparator configured to output the digital data corresponding to an output current of the integrator based on a reference voltage.

13. The CiM device of claim 12, wherein each of the ADCs further includes a trans-impedance amplifier (TIA) configured to convert and amplify the output current of the integrator into a voltage signal and configured to provide the voltage signal to the comparator.

14. The CiM device of claim 11,
wherein each of the second synaptic cells has substantially the same configuration as each of the first synaptic cells,
wherein each of the first synaptic cells includes:
a first cell transistor having a first electrode coupled to a source line of the corresponding column line, a gate electrode coupled to a positive row line, and a second electrode;
a first variable resistance element coupled between a bit line of the corresponding column line and the second electrode;
a second cell transistor having a third electrode coupled to the source line, a gate electrode coupled to a negative row line, and a fourth electrode; and
a second variable resistance element coupled between the bit line and the fourth electrode, and wherein a corresponding read current is output through the bit line.

15. The CiM device of claim 1, further comprising a row control circuit configured to apply, to the row lines, the pulse signals corresponding to pixel data.

16. The CiM device of claim 15, wherein the row control circuit includes one of:
a pulse width modulator (PWM) for generating the pulse signals according to a width of the pixel data, and
a pulse amplitude modulator (PAM) for generating the pulse signals according to an amplitude of the pixel data.

17. A neuromorphic device comprising:
a plurality of pre-synaptic neurons;
a plurality of first synaptic cells coupled to the pre-synaptic neurons through a plurality of row lines and configured to output a plurality of read currents through a plurality of column lines;
a plurality of second synaptic cells coupled to the pre-synaptic neurons through the row lines and configured to output two or more reference read currents through respective reference column lines; and
a plurality of post-synaptic neurons coupled to the first synaptic cells through the column lines and coupled to the second synaptic cells through the reference column lines and configured to output digital signals by compensating for the read currents output through the column lines based on the reference read currents output through the reference column lines.

18. The neuromorphic device of claim 17,
wherein the reference column lines are provided in an even number, and
wherein all of the second synaptic cells coupled to an odd-numbered reference column are programmed in a high-resistance state (HRS) and all of the second synaptic cells coupled to an even-numbered reference column line are programmed in a low-resistance state (LRS).

19. The neuromorphic device of claim 17, wherein each of the post-synaptic neurons includes an analog-to-digital converter configured to generate a replica current by reflecting a specific weight on an average value of the reference read currents and configured to compensate for an offset of a corresponding read current by subtracting the replica current from the corresponding read current.

20. The neuromorphic device of claim 19, wherein each of the post-synaptic neurons further includes an output circuit configured to output digital data by applying an activation function onto the digital signals and by performing a multiplication and accumulation computation on the digital signals to which the activation function is applied.

21. An operating method of a Computation-in-Memory (CiM) device, the operating method comprising:
applying, through a plurality of row lines, pulse signals corresponding to pixel data to a plurality of first synaptic cells and a plurality of second synaptic cells, the first synaptic cells being disposed between the row lines and a plurality of column lines and the second synaptic cells being disposed between the row lines and two or more reference column lines;
outputting a plurality of read currents corresponding to the pulse signals through the column lines;
outputting two or more reference read currents corresponding to the pulse signals through the respective reference column lines; and
outputting digital data by compensating for the read currents output through the column lines based on the reference read currents output through the reference column lines.

22. The operating method of claim 21,
wherein the reference column lines are provided in an even number, and
further comprising:
programming all of the second synaptic cells coupled to an odd-numbered reference column line in a high-resistance state (HRS); and
programming all of the second synaptic cells coupled to an even-numbered reference column line in a low-resistance state (LRS).

23. The operating method of claim 21, wherein the compensating for the read currents includes:
calculating an average value of the reference read currents;
generating a replica current by reflecting a specific weight between 0 and 1 on the average value; and
compensating for offsets of the read currents by subtracting the replica current from the read currents.
